(19) United States
(12) Patent Application Publication
(10) Pub. No.: US 2026/0002814 A1
(43) Pub. Date: Jan. 1, 2026

(54) Circuit Board for Flat Plate Calorimeter

(71) Applicants: David O. Hubble, King George, VA (US); Peter L. Wick, JR., Fredericsburg, VA (US); Larry Justin Stiltner, King George, VA (US)

(72) Inventors: David O. Hubble, King George, VA (US); Peter L. Wick, JR., Fredericsburg, VA (US); Larry Justin Stiltner, King George, VA (US)

(73) Assignee: United States of America, as represented by the Secretary of the Navy, Arlington, VA (US)

(21) Appl. No.: 18/758,492

(22) Filed: Jun. 28, 2024

(51) Int. Cl. G01J 1/44; G01J 1/42; H05K 1/02

(52) U.S. Cl. CPC G01J 1/44; G01J 1/4257; H05K 1/028

(57) ABSTRACT

A circuit board is provided on a calorimeter plate with obverse and reverse sides for measuring irradiance from a laser that strikes the obverse side via temperature response from the reverse side. The board includes an electrically insulated substrate and an electrically conductive trace. The substrate has first and second surfaces. The substrate mounts to the reverse side along the first surface. The electrically conductive trace is disposed onto the second surface of the substrate.

### STATEMENT OF GOVERNMENT INTEREST

The invention described was made in the performance of official duties by one or more employees of the Department of the Navy, and thus, the invention herein may be manufactured, used or licensed by or for the Government of the United States of America for governmental purposes without the payment of any royalties thereon or therefor.

### BACKGROUND

The invention relates generally to calorimeters. In particular, the invention relates to a circuit board for measuring temperature from an irradiated flat plate.

Directed energy devices, such as a high energy laser (HEL), can be used to deliver electromagnetic energy towards a target. Accurately measuring the downrange power of an HEL system is necessary in order to assess system performance. A flat plate calorimeter (FPC) issued as U.S. Pat. No. 11,326,964—incorporated herein by reference in its entirety—was developed specifically for this task to measure HEL power.

### SUMMARY

Conventional calorimeters yield disadvantages addressed by various exemplary embodiments of the present invention. In particular, various exemplary embodiments provide a circuit board is provided on a calorimeter plate with obverse and reverse sides for measuring irradiance from a laser that strikes the obverse side via temperature response from the reverse side.

The board includes an electrically insulated substrate and an electrically conductive trace. The substrate has first and second surfaces. The substrate mounts to the reverse side along the first surface. The electrically conductive trace is disposed onto the second surface of the substrate. Other various embodiments additionally provide for the trace forming a spiral and being composed of copper.

### BRIEF DESCRIPTION OF THE DRAWINGS

These and various other features and aspects of various exemplary embodiments will be readily understood with reference to the following detailed description taken in conjunction with the accompanying drawings, in which like or similar numbers are used throughout, and in which:

FIG. 1 is isometric and elevation cross-sectional views of a flat plate calorimeter;

FIG. 2 is a perspective view of an exemplary trace calorimeter; and

FIG. 3 is a plan view of conductive trace geometries.

### DETAILED DESCRIPTION

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

The disclosure generally employs quantity units with the following abbreviations: length in meters (m), feet (′) or inches (″), mass in grams (g), time in seconds (s), angles in degrees (°) , force in newtons (N), temperature in kelvins (K), energy in joules (J), power in watts (W), and frequencies in hertz (Hz). Supplemental measures can be derived from these, such as density in grams-per-cubic-centimeters (g/cm³), moment of inertia in gram-square-centimeters (kg-m²) and the like.

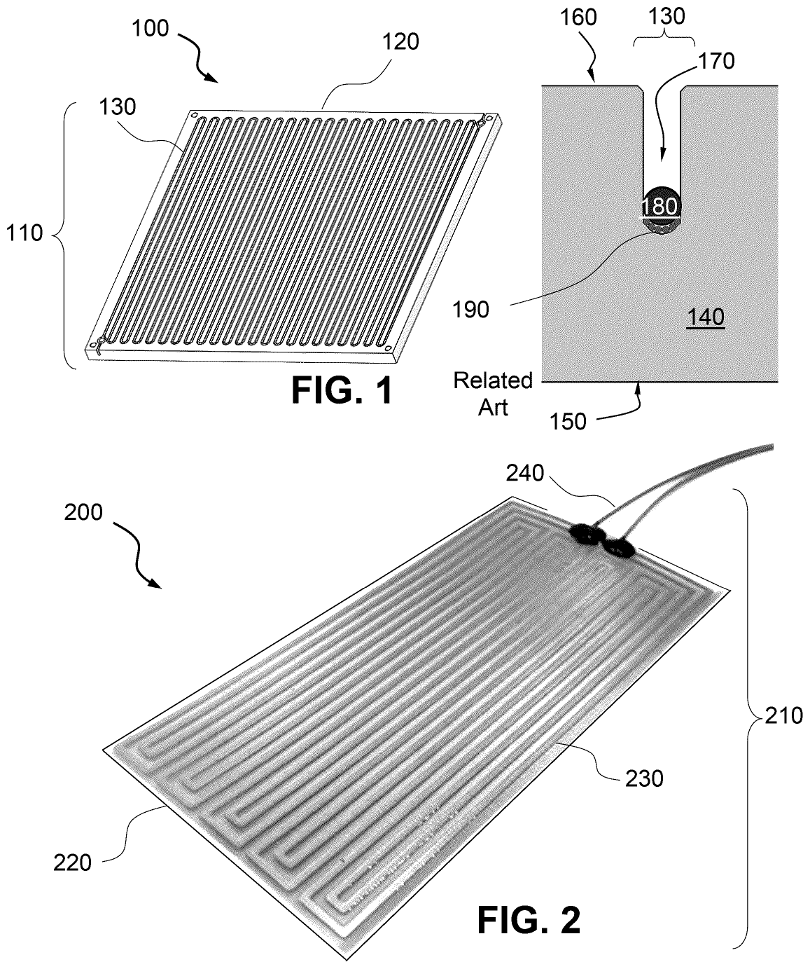

FIG. 1 shows isometric and cross-sectional views 100 of the FPC 110 from the '964 patent featuring a frame 120 that encompasses a resistance temperature detector (RTD) weave of grooves 130 onto an energy absorber plate 140 of metal, such as copper (Cu). The obverse side 150 of the plate 140 receives the HEL emission, while the reverse side 160 contains the grooves 130.

Each groove 130 includes a channel 170 containing an O-ring 180 that secures enamel coated copper wires 190 approximately 30 gauge (0.010″) at the bottom. These grooves 130 are machined onto the reverse side 160 of the plate 140. The wires 190 are held in continuous and uniform thermal contact in the channel 170 at its bottom by the O-ring 180 compressed into the groove 130.

The FPC 110 has demonstrated its ability to accurately measure the downrange performance of HEL systems. One drawback of the design involves the grooves 130 to house the sensing wire 190 required for FPC operation. Machining this groove 130 is extremely time consuming and constitutes the single largest expense in FPC fabrication.

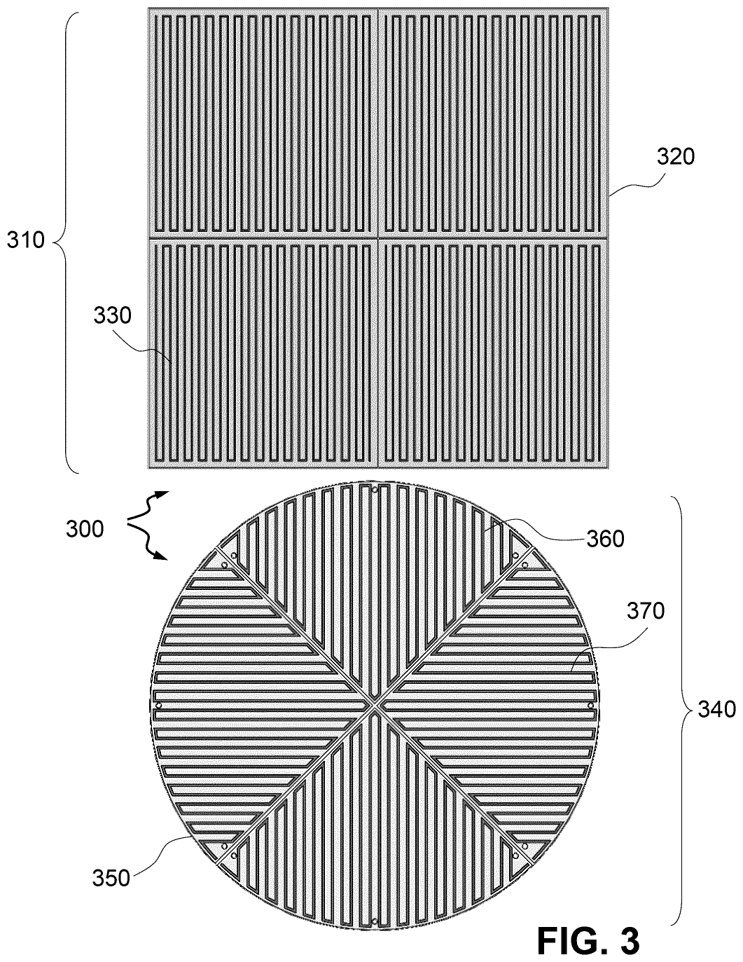

FIG. 2 shows a perspective view 200 of an exemplary generic circuit board 210. An electrically insulating substrate 220, shown as a rectangular flat plate exposing the obverse side, supports an electrically conductive spiraling trace 230 deposited thereon.

Exemplary embodiments provide the premanufactured circuit board 210, which adheres to the absorbing plate 140. The conductive (typically metal) trace 230 on the circuit board 210 replaces the sensing wire 190 and eliminates the need for machining a groove 130 into the absorber plate 140. This single alteration reduces fabrication costs by about an order of magnitude.

The trace 230 encompasses the obverse surface of the substrate 220, although the geometry can vary. For example, a parallel zig-zag (i.e., back-and-forth or side-to-side) pattern, or alternately a conformal spiral, such as the rectangular configuration in view 200 can be arranged.

A connecting wire 240 enables communication with a data acquisition system, such as a digital multimeter, which measures the electrical resistance of the trace 230. This resistance can be correlated to temperature based on the electrical properties of the trace material, such as copper.

The flat plate geometry of the substrate 220 imposes sufficient cohesiveness to enable deposition of a trace 230 without disintegration. The electrical insulation properties of the substrate 220 permit its material to be an inexpensive polymer. The substrate 220 can also include weep holes between the traces 230 to facilitate removal of excess adhesive that would be applied to secure the board 210 to the plate 140 on its reverse side 160. Depending on applicable preference, the substrate 220 can be rigid. Alternatively, the substrate 220 can be elastically flexible or else plastically deformable to enable conformal attachment to a reverse plate surface of continuous curvature.

FIG. 3 shows plan views 300 of circuit trace geometries, such as the spiral trace 230 for disposition on a substrate 220. In particular, a rectangular pattern 310 shows a set of four panel sections 320, each with a back-and-forth or parallel zig-zag “vertical” trace 330 of uniform length.

Further, a circular arrangement 340 provides pie-shape wedge segments 350 divided by right angles. The upper and lower segments provide back-and-forth or parallel zig-zag “vertical” traces 360 with lengths conforming to the segment 350. The lateral left and right segments provide back-and-forth or parallel zig-zag “horizontal” traces 370, also with conforming lengths.

Two working prototype FPCs with the exemplary circuit board 210 have been demonstrated: a spinning circular plate and a static rectangular plate, each mounted to a support frame 120. The circular arrangement 340 can be used for a spinning FPC described in U.S. Patent Application Publication 2023/0152167 (Navy Case 211255). The spinning circuit board FPC has been tested at power ranges from 0.5 KW to 101 kW, with response output linear to R²=.9997.

The patented wire-in-groove FPC configuration 110 has been shown to be accurate and durable but difficult and expensive to fabricate. For example, the groove 130 on a 28″ square FPC plate 140 is 260′ long and only 1/16″ wide. Machining a groove 130 that long and narrow requires up to eighty hours on a large computer numerical controlled (CNC) milling machine.

To solve this difficulty, a new fabrication technique has been developed. The premanufactured circuit board 210 replaces the groove 130, O-ring 180, and sensing wire 190. The exemplary premanufactured board 210 comprises the single layer conductive trace 230 deposited onto the insulating substrate 220, which attaches to the reverse surface 160 of the absorber plate 140 via commonly available adhesive bonding.

For a sufficiently thin substrate 220 uniformly bonded on its reverse side (opposite the trace 230) to the reverse side 160 of the absorber plate 140, the conductive trace 230 remains in near thermal equilibrium with the plate's material, and thus the trace's resistance can accurately measure the average temperature of the plate 140.

An ideal trace material would have a perfectly linear temperature coefficient of resistivity (TCR). While no material exhibits this behavior perfectly, copper (Cu) is a near ideal material. Platinum (Pt) is slightly more linear but orders of magnitude more expensive than copper.

The wire-in-groove FPC 110 and the circuit board FPC 210 function identically and can utilize the same hardware except for the absorber plate 140. For the circuit board manufacturing method, the groove 130 can be omitted from the absorber plate 140, which only requires mounting holes or other features for affixing to its support base. The only machining required of the reverse surface 160 is a slight roughening to facilitate chemical bonding of the circuit board substrate 220 with an appropriate adhesive. Furthermore, the circuit board 210 is not required to be as large in surface area as the absorber plate 140.

As shown in view 300, several smaller circuit boards 320 and 360 can be “tiled” onto the reverse surface 160 and then wired in series. This is shown conceptually for both square 310 and circular 350 absorber plates. In both cases, four separate circuit boards 320 or 360 are used in place of a single large circuit board 210. Utilizing several smaller circuit boards 320 or 360 to replace a single large unit 210 further reduces material costs.

The circuit board 210 must be thoroughly and uniformly bonded to the reverse side 160 of the absorber plate 140 in order to accurately measure its average temperature. This is accomplished using compatible adhesives and vacuum bagging techniques. The substrate 220 can include numerous weep holes disposed between the traces 230 to enable excess adhesive to pass therethrough to enable uniform separation between the substrate 220 and the absorber plate 140.

After the adhesive is spread onto the back of the absorber plate 140, the circuit board 210 is aligned and inserted inside a vacuum bag. A vacuum pump removes the air from the bag through the vacuum hose. Atmospheric pressure applies even clamping pressure across the entire surface until the adhesive cures.

The primary advantage of the exemplary construction technique presented herein involves diminishing burden of manufacture. Elimination of the groove 130 in which the sensing wire 190 was deposited greatly reduces the time and cost of production. Additionally, by utilizing an automated procedure for fabricated the sensing trace 220 rather than manual wiring, overall repeatability of the measurement instrument is improved.

By utilizing elastically flexible substrates, one can bond the circuit board 210 to the reverse side 160 of a curved geometry. This enables measuring laser power on a cylindrical section or other non-planar surface, which would be nearly impossible to accomplish using the prior wire-in-groove methodology.

While certain features of the embodiments of the invention have been illustrated as described herein, many modifications, substitutions, changes and equivalents will now occur to those skilled in the art. It is, therefore, to be understood that the appended claims are intended to cover all such modifications and changes as fall within the true spirit of the embodiments.

What is claimed is:

1. A flat plate calorimeter for measuring irradiance from a laser via temperature response, calorimeter comprising:
a circuit board having an electrically insulated substrate having first and second surfaces, and an electrically conductive trace disposed on said first surface; and
a platform for receiving the irradiance on an obverse side and mounting said second surface of said substrate onto a reverse side.

2. The plate according to claim 1, wherein said trace forms a parallel zig-zag pattern.

3. The plate according to claim 1, wherein said trace is copper.

4. A circuit board on a calorimeter plate with obverse and reverse sides for measuring irradiance from a laser that strikes said obverse side via temperature response from said reverse side, said board comprising:
an electrically insulated substrate having first and second surfaces, said substrate mounted to the reverse side along said first surface; and
an electrically conductive trace disposed onto said second surface of said substrate.

5. The circuit board according to claim 4, wherein said substrate is elastically flexible.

6. The circuit board according to claim 4, wherein said trace forms a parallel zig-zag pattern.

7. The circuit board according to claim 4, wherein said trace is copper.
